(19) United States
(12) Patent Application Publication
(10) Pub. No.: US 2007/0279068 A1
(43) Pub. Date: Dec. 6, 2007

(54) Power diagnostic system and method

(76) Inventor: Daniel N. Harres, Belleville, IL (US)

Correspondence Address: KLEIN, O'NEILL & SINGH, LLP, 43 CORPORATE PARK, SUITE 204, IRVINE, CA, 92606, US

(21) Appl. No.: 11/443,864

(22) Filed: May 31, 2006

(51) Int. Cl. G01R 31/08

(52) U.S. Cl. 324/522

(57) ABSTRACT

A power diagnostic system and method for detecting faults is provided. The system includes a processor coupled to a plurality of sampling blocks; wherein the plurality of sampling blocks simultaneously perform current measurements and voltage measurements at a plurality of loads, based on a reference signal generated by a clock generator; wherein the sampling blocks measurements are sent to the processor via power cables that are also used to supply power to the plurality of loads. The method includes sampling currents and voltages at a power supply and at a plurality of loads; wherein the sampling is synchronized to a reference signal; transmitting sampled currents and voltages to a processor; comparing sampled currents and voltages with threshold values; and identifying faults if the sampled currents and voltages vary from the threshold values.

### CROSS-REFERENCE TO RELATED APPLICATIONS

None

### BACKGROUND OF THE INVENTION

1. Field of the Invention

The present invention relates generally to power systems, and more particularly, to locating fault conditions in such systems.

2. Description of the Related Art

Power cable integrity is an important issue in various systems, for example, modern aircraft and automotive applications. To diagnose a hard failure, such as an open or a short, is generally a straightforward task. However, diagnosing an intermittent arcing fault, a common problem in these applications, is much more difficult. Such a fault can lead to system failure. In an extreme case, it can result in a catastrophic event such as an explosion.

Arcing faults can be grouped into three categories relative to their current path location in the electrical circuit: (a) Parallel arcing, in which the arc occurs between power cables and its associated return; (b) Series arcing, in which the arc occurs in series with the load; and (c) Ground-fault or leakage fault, in which the power cable arcs to some conductor not associated with normal power transfer in the system.

FIGS. 1A through 1C show the three fault types schematically. FIG. 1A shows parallel arcing (107) between power cable (104) and its return. Power is supplied by source 101 to load 121. Fault 107 appears as an intermittent short between cables 104. FIG. 1B shows series arcing 108, where an intermittent open occurs in series with the load. FIG. 1C shows ground arcing 109, where the power cable arcs to a grounded conductor.

Traditional methods of detecting such faults, for example, circuit breakers and ground fault interrupters, are inadequate for intermittent arcing fault detection. The circuit breaker will not trip for a series fault; for parallel or ground faults, it will generally require a long fault duration and sufficient current increase from the fault to trip the breaker. In most cases, the current increase caused by the arcing tends to be significantly lower than the trip current. Ground fault interrupters, which operate by comparing the source and return currents to insure that no leakage current occurs, can properly protect against the ground fault but will have no effect on a parallel or series arcing fault.

Conventional techniques commonly use waveform distortion technique or DC-feedback technique for detecting faults. The waveform distortion technique relies on the fact that an arcing fault will generally cause an abrupt change in either voltage or current or both. The principle here is that in the event of an abrupt change in the voltage or current waveform, the harmonic spectral content will increase significantly. Such detection methods are susceptible to false alarms due to the difficulty of discriminating fault events from normal abrupt changes of the load or the environment.

DC power lines typically use the DC-feedback technique. The arcing faults are detected by performing differential measurements of input and load currents and input and load voltages. The differential measurement scheme has disadvantages because it typically uses additional cables between power source and each load. This adds cost, weight, complexity and reduces system reliability.

Therefore, there is a need for a method and a system for detecting and identifying power cable arcing faults without the foregoing disadvantages.

### SUMMARY OF THE INVENTION

In one aspect of the present invention, a power diagnostic system for detecting faults is provided. The system includes a processor coupled to a plurality of sampling blocks; wherein the plurality of sampling blocks simultaneously perform current measurements and voltage measurements at a plurality of loads, based on a reference signal generated by a clock generator; and the sampling blocks measurements are sent to the processor via power cables that are also used to supply power to the plurality of loads.

In another aspect of the present invention, a method for detecting faults in a power system is provided. The method includes sampling currents and voltages at a power supply and at a plurality of loads; wherein the sampling is synchronized to a reference signal; transmitting sampled currents and voltages to a processor; comparing sampled currents and voltages with threshold values; and identifying faults if the sampled currents and voltages vary from the threshold values.

This brief summary has been provided so that the nature of the invention may be understood quickly. A more complete understanding of the invention can be obtained by reference to the following detailed description of the preferred embodiments thereof in connection with the attached drawings.

### BRIEF DESCRIPTION OF THE DRAWINGS

The above and other objects, features, and advantages of the present invention will be more apparent from the following detailed description taken in conjunction with the accompanying drawing. In the drawings, the same components have the same reference numerals. The illustrated embodiment is intended to illustrate, but not to limit the invention. The drawings include the following figures:

FIG. 1A shows a simple illustration of a parallel arc;

FIG. 1B shows a simple illustration of a serial arc;

FIG. 1C shows a simple illustration of a ground arc;

FIG. 2 is a block diagram shows a conceptual arrangement of a Power Diagnostic System, according to the present invention;

FIG. 3 shows a block diagram of a sampling block; and

FIG. 4 is a flowchart illustrating the operation of a Power Diagnostic System, according to another embodiment of the present invention.

### DETAILED DESCRIPTION OF THE PREFERRED EMBODIMENTS

Hereinafter, preferred embodiments of the present invention will be described with reference to the accompanying drawings. A detailed description of known functions and configurations incorporated herein will be omitted when it may obscure the subject matter of the present invention.

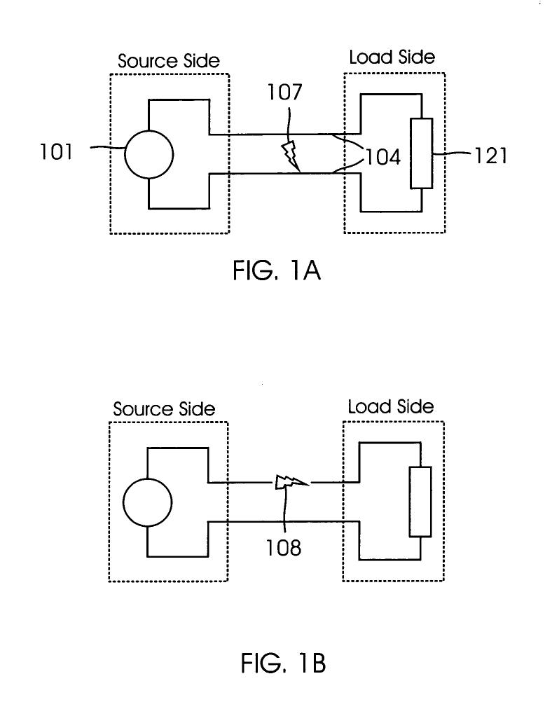

One aspect of the present invention provides a power diagnostic system and method capable of detecting and identifying power cable arcing faults. For parallel and ground-fault arcing, as depicted in FIG. 1A and FIG. 1C a fault event is detected by an efficient bookkeeping technique. Current and voltage samples are collected at each load synchronously, controlled by a clock generator. The sampled currents and voltages are sent to a processor, preferably via existing power cables. The processor compares and analyzes the sampled currents and voltages to determine fault conditions. Since the sum of currents measured at the loads must equal the current at the source, i.e. at the power supply, any significant deviation from that requirement indicates a fault.

Series fault is detected based on when an open-circuit occurs in the power cables, DC voltage level at the load will decrease. This decrease happens even when the DC voltage at the load is kept constant by a bypass capacitor. For example, the loss of the “hot” side of a 28 VDC load input, with 1000 μF bypass capacitance and with 1 A load current, will drop the DC voltage level by 1 Volt per millisecond, a substantial change that can be detected with even low-precision instrumentation.

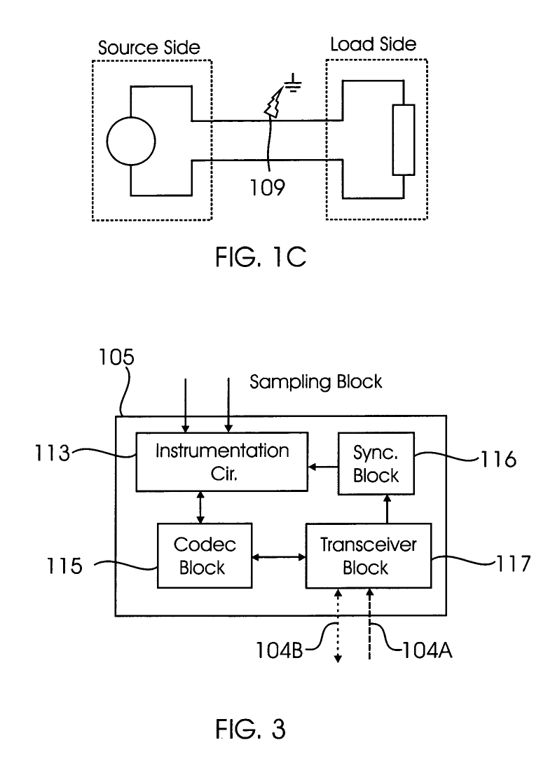

FIG. 2 illustrates a functional block diagram of a power diagnostic system 100A, according to one aspect of the present invention. System 100A includes a power supply 101 that supplies power to a plurality of loads (shown as 121, 131 and 141), a central diagnostic unit 100, a plurality of field replaceable units (FRU)s 120, 130, and 140 all of them connected together by power cables 104 through their power terminals (110A, 121A 131A and 141A).

Central diagnostic unit 100 includes a processor unit 103, a sampling block 105, and a clock generator 102.

Processor unit 103 executes computer-executable process steps, interfacing with a plurality of sampling blocks (105, 125, 135, and 145), performing sample comparison, fault identification, data logging, and other general “house keeping” functions, as described below.

Clock generator 102 provides a clock reference signal for each of the sampling blocks 105, 125, 135 and 145 to facilitate synchronous sampling action. The sampling blocks 105 125, 135 and 145 are phase-locked to the clock reference signal.

Individual sampling blocks 125, 135 and 145, are connected to each load 121, 131 and 141, through power terminals 121A, 131A and 141A respectively forming FRUs 120, 130 and 140. The sampling blocks 105, 125, 135 and 145 are identical in principal, although differences in implementation are possible to make them more adaptable to a particular load.

Sampling blocks 105, 125, 135 and 145 collect voltage and current measurements, synchronously, as controlled by clock generator 102 generated reference signals. The measurements are sent to processor 103 via power cables 104. Processor 103 sums the current measurements and compares that sum to its own measured output current. Processor 103 also compares each of the measured load voltages and compares them, individually, to its own measured output voltage. If either the sum of the load currents or any of the individual load voltages deviate significantly from the output current or output voltage, respectively, a fault condition is detected/identified.

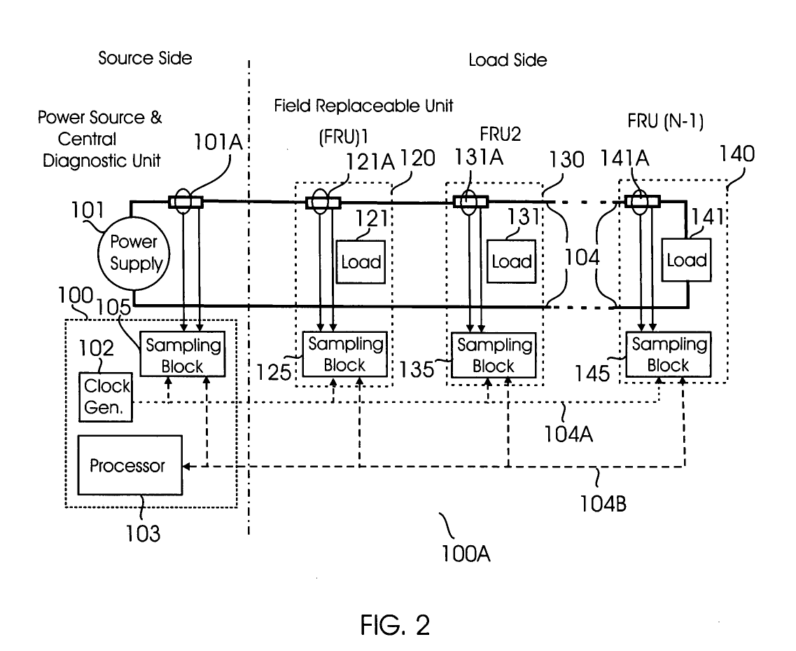

FIG. 3 is a block diagram of a sampling block 105. Sampling block 105 includes an instrumentation block 113, a synchronization block 116, a codec block 155 and a transceiver block 117 that are described below. It is noteworthy that the present invention is not limited to the plural functional components of sampling block 105. A specialized application specific integrated circuit (ASIC) or a processor can be used to perform the various functions described below.

Instrumentation block 113 performs all current and voltage measurements at the respective power terminal. The accuracy and resolution of instrumentation block 113 can be enhanced if needed by using various calibration and compensation techniques. The resolution enhancement features could all be controlled by central diagnostic unit 100.

During voltage measurements, there are two main sources for measurement uncertainty, instrumentation errors, and resolution limitation. Instrumentation errors are due to circuits and circuit components like resistor dividers, amplifiers, A/D converter and others that are used to perform the measurements. The errors in these circuits can be calibrated by providing a voltage reference at each node.

During a series arc event, the input current, in addition to the DC input voltage will drop significantly, this current drop changes the IR drop on the power cables 104. The detection capability is improved by accounting for the IR drop. A measured input current can be used to compute the IR as shown in Equation (1):

V_{source}=V_{load}+IR Equation (1)

where I is the input current at the load and R is the resistance of the power cables 104.

Fault detection precision is also limited by methodical measurement error. This is cumulative measurement error at N different locations (source plus N−1 loads). Since arcing could cause relatively small amounts of current that may not be distinguishable from large changes in a dominant load, it is important to minimize the accumulated error. In one aspect of the present invention, processor 103 provides compensation to balance source output and load inputs under normal (no fault) operating conditions and by doing so enhances the resolution of the detection system.

The current measurements have an additional source of error originating from the current sensor. Typically, industry grade DC current sensors are capable of 0.5% accuracy over −40° C. to 85° C. temperature range and are hence adequate.

Synchronization block 116 can be implemented using a phase lock loop (PLL) or other synchronous circuits to establish precise sampling times. In the present invention, the phase lock loop with 50 Hz bandwidth has reasonable acquisition times and it is impervious to large spikes and other noise phenomena existing on power cables 104.

Codec block 115 performs data translation between instrumentation block 113 and transceiver block 117. It encodes measurement and status data transmitted by transceiver 117 to processor 103 and decodes commands/instructions received by transceiver 117 from processor 103.

Transceiver block 117 provides a communication means between central diagnostic unit 100 and the plurality of FRU's 120, 130 and 140, using the power cables 104 as communication medium. Orthogonal Frequency-Division Multiplexing (OFDM), Direct-Sequence Spread Spectrum (DSSS) or other modulation techniques can be used to send information from sampling blocks 105, 125, 135, and 145 back to the processor 103 directly on the power cables 104. Such communication would likely incorporate a Forward Error Correction (FEC) scheme in order to avoid “fades” that occurs due to large amplitude spikes on the media. Alternatively, fiber optic cable can be used as the transmission medium. Instead of using power cables 104, sampling blocks can transmit data via connection 104B. Similarly, clock generator 102 can transmit reference signal via connection 104A.

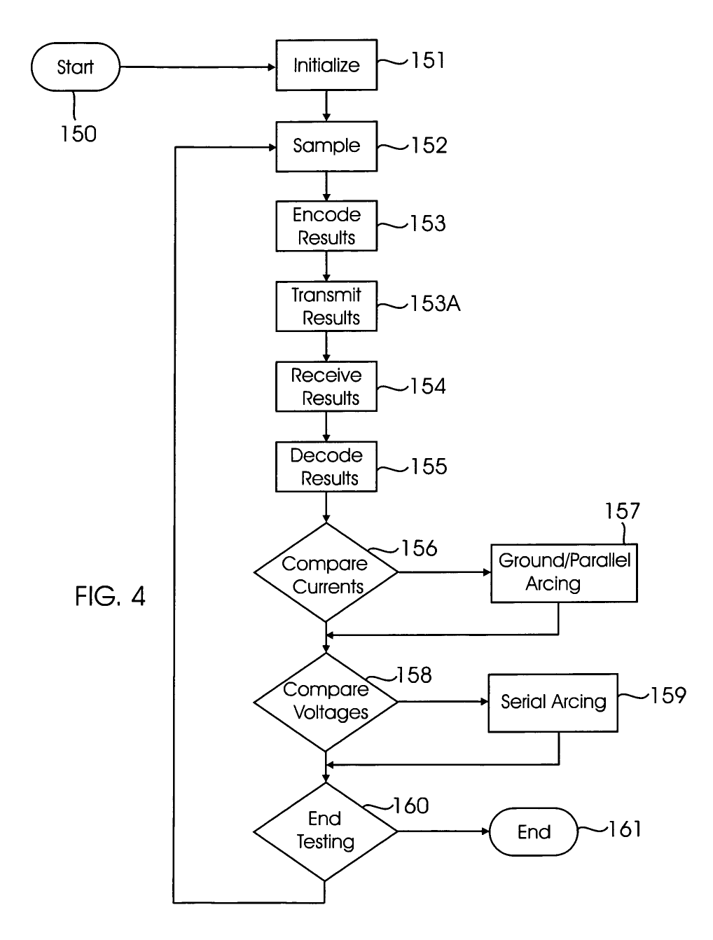

FIG. 4 shows a process flow diagram for detecting fault conditions, according to yet another aspect of the present invention. The process starts in step 150 and in step 151, the system 100A is initialized. During initialization, power is provided to loads 121, 131 and 141, and clock generator 102 is enabled. The sampling blocks 105, 125, 135 and 145 are synchronized based on a reference signal generated by clock generator 102, and the system's basic functionalities are verified. In step 152, currents and voltages are sampled. This sampling is synchronized (i.e. samples are taken simultaneously).

In step 153, the sampled currents and voltages are encoded. In step 154, the encoded data is transmitted to central diagnostic unit 100. The data is received in step 154, and in step 155, the encoded data is decoded.

In step 156, load currents are summed by processor 103, if needed, compensation can be applied, and then currents are compared. In one aspect, I_{load} is sum of all the measured currents and it is compared to the current that was supplied by power supply 101 (I_{supply}).

If the sum of the measured currents deviates from the source current beyond a threshold limit, then in step 157, ground/parallel arcing is detected. For example, if the difference between the measured current and supplied current is I_{Δ} and it exceeds a predetermined value, then it denotes that ground/parallel fault condition exists. I_{Δ} is computed by using Equation (2):

I_{Δ}=I_{supply}−I_{load} Equation (2)

As stated above, I_{supply} is the current provided by the power supply 101 and I_{load} is the sum of all of all the load currents.

After the current compare, the voltage samples are compared in step 158. Comparison results are the basis serial arcing detection and identification.

When the voltage difference of any consecutive sample exceeds a predetermined value, serial arcing is detected, as shown in step 159. This voltage difference is expressed by Equation (3):

V_{Δ}=Vₙ₋₁−Vₙ Equation (3)

where Vₙ₋₁ and Vₙ are any two consecutively taken voltage readings

### In another aspect of the present invention, measured voltages are compared to the source voltage to detect serial arcing.

The present invention provides numerous advantages over previous approaches to power diagnosis. Measurements are performed at loads and at power supply, providing better accuracy enhancing the fault detection capability. Data collection method is tolerant of noise on the transmission medium. Having a central processor unit makes the system more flexible and more economical to implement. Furthermore, additional cables are not needed and hence is very useful in weight sensitive operations (for example, aircrafts, space shuttle and others).

Although the present invention has been described with reference to specific embodiments, these embodiments are illustrative only and not limiting. Many other applications and embodiments of the present invention will be apparent in light of this disclosure and the following claims.

What is claimed is:

1. A power diagnostic system comprising:
a processor coupled to a plurality of sampling blocks; wherein the plurality of sampling blocks simultaneously perform current measurements and voltage measurements at a plurality of loads based on a reference signal generated by a clock generator; and the sampling blocks measurements are sent to the processor via power cables that are also used to supply power to the plurality of loads.

2. The power diagnostic system of claim 1, wherein the sampling block includes;
an instrumentation block for performing voltage and current sampling at power terminals for the plurality of loads; and
a synchronization block that synchronizes sampling of currents and voltages with the reference signal.

3. The power diagnostic system of claim 2, wherein the sampling block includes a codec block for transforming information received from the instrumentation block and a transceiver block.

4. The power diagnostic system of claim 3, wherein the transceiver block communicates with the processor.

5. A method for finding faults in a power system, comprising:
sampling currents and voltages at a power supply and at a plurality of loads; wherein the sampling is synchronized to a reference signal;
transmitting sampled currents and voltages to a processor;
comparing sampled currents and voltages with threshold values; and
identifying faults if the sampled currents and voltages vary from the threshold values.

6. The method of claim 5, wherein the reference signal is generated by a clock generator.

7. The method of claim 5, wherein sampled currents and sampled voltages are transmitted to the processor is using Ethernet.

8. The method of claim 5, wherein sampled currents and sampled voltages are transmitted to the processor using power cables.

9. The method of claim 5, wherein the comparing step, comprising;
summing sampled load currents;
comparing sum of the load currents to a source current; and
comparing consecutive voltage readings.

10. The method of claim 5, wherein serial arcing is detected.

11. The method of claim 5, wherein parallel arcing is detected.

12. The method of claim 5, wherein ground arcing is detected.

13. The method of claim 5, wherein the power system is used in aircrafts.

14. The method of claim 5, wherein the power system is used in automotive systems.
